(19) United States
(12) Patent Application Publication
(10) Pub. No.: US 2009/0191655 A1
(43) Pub. Date: Jul. 30, 2009

(54) METHOD OF ETCHING AMORPHOUS SILICON LAYER AND METHOD OF MANUFACTURING LIQUID CRYSTAL DISPLAY USING THE SAME

(76) Inventors: Shin-Il Choi, Seoul (KR); Sang-Gab Kim, Seoul (KR); Seung-Ha Choi, Siheung-si (KR); Gon-Ho Kim, Anyang-si (KR); Min-Seik Oh, Yongin-si (KR); Hong-Kee Chin, Suwon-si (KR); Yu-Gwang Jeong, Yongin-si (KR)

Correspondence Address: F. CHAU & ASSOCIATES, LLC, 130 WOODBURY ROAD, WOODBURY, NY, 11797, US

(21) Appl. No.: 12/200,430

(22) Filed: Aug. 28, 2008

(30) Foreign Application Priority Data
Jan. 28, 2008 (KR) 10-2008-008683

(51) Int. Cl. H01L 21/3065; H01L 33/00

(52) U.S. Cl. 438/30; 438/715; 257/E21.218; 257/E33.053

(57) ABSTRACT

A method of etching an amorphous silicon layer includes providing a substrate with an amorphous silicon layer formed thereon into an atmospheric pressure plasma etching device, providing a plasma generation gas and etching gas to a plasma generator of the atmospheric pressure plasma etching device and generating an atmospheric pressure plasma gas between two electrodes provided in the plasma generator in which the two electrodes face each other. The method further includes repeatedly passing the substrate through the plasma generator at a predetermined speed, thereby etching the amorphous silicon layer on the substrate by using the atmospheric pressure plasma gas generated from the plasma generator.

### CROSS-REFERENCE TO RELATED APPLICATION

This application claims priority form Korean Patent Application No. 2008-08683 filed on Jan. 28, 2008, the disclosure of which is hereby incorporated by reference in its entirety.

### BACKGROUND

1. Technical Field

The present disclosure relates to a method of etching an amorphous silicon layer and to a method of manufacturing a liquid crystal display using the same. More particularly, the present disclosure relates to a method of etching an amorphous silicon layer using atmospheric pressure plasma gas and to a method of manufacturing a liquid crystal display using the etching method.

2. Description of the Related Art

Generally, a semiconductor manufacturing device includes a thin film forming device that forms a thin film on a semiconductor substrate, a photolithography device that forms a mask pattern on the thin film to form a fine pattern, an etching device that forms the fine pattern by etching the thin film, and an ion implantation device that implants ions into the semiconductor substrate.

Recently, as semiconductor devices have become more highly integrated, the line width of the fine pattern have become gradually narrowed. Accordingly, the etching device used to form the fine pattern has become more important. Generally, the etching device is classified into a plasma etching device and a wet etching device. As the integration degree of a semiconductor device is increased, a plasma etching device exhibiting an anisotropic property is mainly used.

In addition, conventionally, the plasma etching device is generally used to etch a layer necessary for a liquid crystal display that is one of display devices.

The conventional plasma etching device is a vacuum plasma etching device, and etches a layer by using plasma gas generated under high vacuum environment. Recently, as the size of a liquid crystal display has become enlarged, the size of a substrate has also been increased. Accordingly, the conventional vacuum plasma etching device, which is used to etch a layer provided on the substrate, now may require high vacuum pumps to support a large-sized vacuum container and to maintain a high degree of vacuum.

However, it may be difficult to enlarge a vacuum container proportionally to the increase of the size of the substrate. In addition, the enlarged substrate may the increase the cost to use the high vacuum pump, such that the manufacturing cost for the liquid crystal display may also increase.

### SUMMARY

Exemplary embodiments of the present invention provide a method of etching an amorphous silicon layer using atmospheric pressure plasma gas.

Exemplary embodiments of the present invention also provide a method of manufacturing a liquid crystal display by using the etching method.

In accordance with an exemplary embodiment of the present invention, a method of etching an amorphous silicon layer is provided. The method includes providing a substrate with an amorphous silicon layer formed thereon into an atmospheric pressure plasma etching device, providing a plasma generation gas and etching gas to a plasma generator of the atmospheric pressure plasma etching device, and generating an atmospheric pressure plasma gas between two electrodes provided in the plasma generator in which the two electrodes face each other. The method further includes repeatedly passing the substrate through the plasma generator at a predetermined speed, thereby etching the amorphous silicon layer on the substrate by using the atmospheric pressure plasma gas generated from the plasma generator.

In accordance with an exemplary embodiment of the present invention, a method of manufacturing a liquid crystal display is provided. The method includes forming an array substrate provided with a thin film transistor, forming an opposite substrate, which is coupled to the array substrate while facing the array substrate, is formed and interposing a liquid crystal layer between the array substrate and the opposite substrate. The thin film transistor is formed on the array substrate by forming a gate electrode, etching an amorphous silicon layer using atmospheric pressure plasma gas to form a semiconductor layer on the gate electrode, and forming a source and drain electrode overlapping with the semiconductor layer.

According to the above, the layer used for the liquid crystal display is etched by using the atmospheric pressure plasma etching device, so that vacuum equipment is not required, and the price of etching equipment is lowered.

### BRIEF DESCRIPTION OF THE DRAWINGS

Exemplary embodiments of the present invention can be understood in more detail from the following description taken in conjunction with the accompanying drawings wherein:

FIG. 1 is a perspective view showing an exemplary embodiment of an atmospheric plasma etching device according to the present invention;

FIG. 2 is a plan view showing the atmospheric plasma etching device shown in FIG. 1;

FIG. 3 is a sectional view showing the atmospheric pressure plasma etching device of FIG. 1;

FIG. 4 is a graph showing an etch rate according to a flow rate of helium gas;

FIG. 5 is a graph showing the etch rate of an amorphous silicon layer according to the movement speed of a substrate;

FIG. 6 is a graph showing etch uniformity according to the movement speed of a substrate;

FIG. 7 is a graph showing an etch rate according to a function of time;

FIG. 8 is a flowchart showing a manufacturing process of a liquid crystal display according to an exemplary embodiment of the present invention;

FIG. 9 is a flowchart showing the procedure of manufacturing an array substrate through a 5-mask process;

FIG. 10 is a flowchart showing the procedure of manufacturing an array substrate through a 4-mask process;

FIG. 11A is a view showing a profile of an active layer including amorphous silicon after etching the active layer by using an atmospheric pressure plasma etching device through a 4-mask process;

FIG. 11B is a view showing a profile of an active layer including amorphous silicon after etching the active layer by using an atmospheric pressure plasma etching device through a 5-mask process;

FIG. 12 is a plan view showing a thin film transistor in the 4-mask process for a liquid crystal display;

FIGS. 13A to 13C are sectional views taken along lines I-I′, II-II′, and III-III′ of FIG. 12

FIG. 14 is a plan view showing a thin film transistor in a 5-mask process for a liquid crystal display;

FIGS. 15A and 15B are sectional views taken along lines IV-IV′ and V-V′ of FIG. 14;

FIG. 16A is a graph representing an off-current measured according to glass numbers;

FIG. 16B is a graph showing an on-current measured according to the glass numbers;

FIG. 16C is a graph showing a threshold voltage measured according to glass numbers;

FIG. 16D is a graph showing parasitic capacitance between a gate and a source measured according to glass numbers;

FIG. 17A is a graph representing an off-current measured according to glass numbers;

FIG. 17B is a graph showing an on-current measured according to glass numbers;

FIG. 17C is a graph showing a threshold voltage measured according to glass numbers;

FIG. 17D is a graph showing parasitic capacitance between a gate and a source according to glass numbers; and

FIG. 17E is a graph showing parasitic capacitance between a drain and a source measured according to glass numbers.

### DESCRIPTION OF THE EXEMPLARY EMBODIMENTS OF THE INVENTION

Hereinafter, exemplary embodiments of the present invention will be explained in more detail with reference to the accompanying drawings.

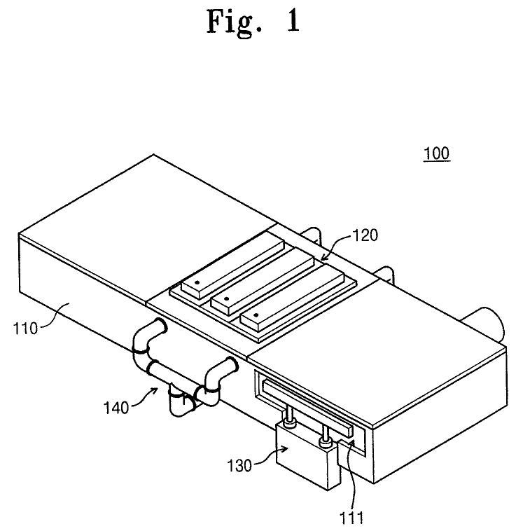

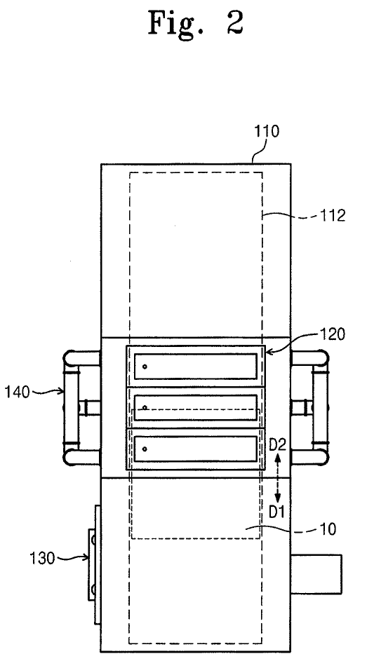

FIG. 1 is a perspective view showing an atmospheric plasma etching device 100 according to an exemplary embodiment of the present invention, and FIG. 2 is a plan view showing the atmospheric plasma etching device 100 shown in FIG. 1.

Referring to FIGS. 1 and 2, the atmospheric plasma etching device 100 includes a chamber housing 110 having a substrate entrance 111, a plasma generator 120 that generates plasma gas to etch a substrate 10, a chamber door 130 that opens/closes the substrate entrance 111, and an exhaust pipe 140 that exhausts process gas from the inside of the chamber housing 110.

The chamber housing 110 has a rectangular box shape and receives therein the substrate 10 introduced through the substrate entrance 111. The substrate entrance 111 is provided at one side of an outer portion of the chamber housing 110. Through the substrate entrance 11, the substrate 10 is introduced into the chamber housing 110, or the substrate 10 is withdrawn to the outside of the chamber housing 110 after the etching process. In addition, a substrate conveying device that conveys the substrate 10 back and forth may also be installed in the chamber housing 110. Accordingly, the substrate 10 introduced into the chamber housing 110 is conveyed by the substrate conveying device in a first direction D1 or second direction D2.

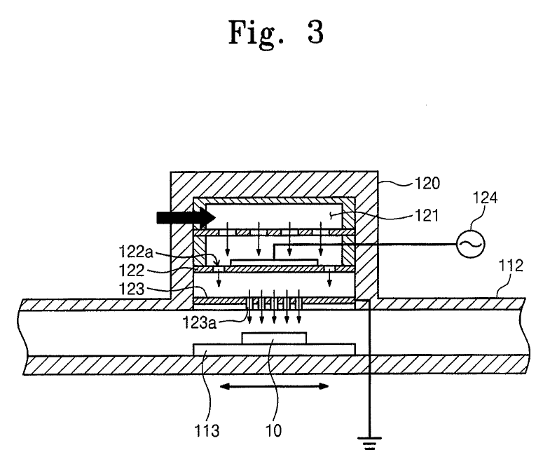

In addition, the chamber housing 110 includes an etching chamber 112 in which an amorphous silicon layer provided on the substrate 10 is etched by plasma. The plasma generator 120 is provided at an upper side of the chamber housing 110 to supply plasma gas into the etching chamber 112. Accordingly, the etching chamber 112 etches the amorphous silicon layer on the substrate 10 by using the plasma gas generated from the plasma generator 120. The structure of the plasma generator 120 will be described with reference to FIG. 3 later.

The chamber door 130 is installed at an outer portion of the chamber housing 110 to open/close the substrate entrance 111. The chamber door 130 opens/closes the substrate entrance 111 while moving up and down through the operation of a chamber door valve. The chamber door 130 opens the substrate entrance 111 only when the substrate 10 is introduced into/withdrawn from the chamber housing 110, and closes the substrate entrance 111 in the etching process, thereby preventing process gas existing inside the etching chamber 112 from flowing out of the etching chamber 112.

The exhaust pipe 140 is installed at an outer portion of the chamber housing 110 and extends inside of the etching chamber 112. The exhaust pipe 140 exhausts process gas and particles existing in the etching chamber 112 to the outside of the etching chamber 120 after the etching process has been performed. In addition, a pump for generating a suction force may be coupled to the exhaust pipe 140. In the present exemplary embodiment, the exhaust pipe 140 is suspended to the front surface of the etching chamber 120 to exhaust gas contained in the etching chamber 112 through an exhaust hole provided at the front surface of the exhaust pipe 140 during the etching process.

If the chamber door 130 descends to open the substrate entrance 111 of the chamber housing 110, the substrate 110 for the etching process is introduced into the chamber housing 110 through the substrate entrance 111. If the substrate 10 has been introduced into the chamber housing 110, the chamber door 130 ascends by the chamber door valve to close the substrate entrance 111. After the substrate entrance 111 is closed, the substrate 10 is conveyed back and forth by the substrate conveying device such that the substrate 10 repeatedly passes through the etching chamber 112. At this time, while a high voltage is applied to the plasma generator 120, process gas is supplied to generate plasma gas, and the plasma gas is supplied to the etching chamber 112, thereby etching an amorphous silicon layer provided on the substrate 10 reciprocating in the etching chamber 112 by using the plasma gas.

If the etching process for the amorphous silicon layer has been performed, the substrate 10 is positioned at the rear portion of the substrate entrance 111, and the exhaust pipe 140 operates to exhaust process gas and particles in the etching chamber 112 to the outside of the chamber housing 130. Thereafter, the chamber door 130 descends to open the substrate entrance 111, and the substrate 10 is withdrawn to the outside of the chamber housing 110 through the substrate entrance 111. Thus, the etching process for the amorphous silicon layer on the substrate 10 is completed.

FIG. 3 is a sectional view showing the atmospheric pressure plasma etching device 100 of FIG. 1.

Referring to FIG. 3, the plasma generator 120 is provided at the upper portion of the chamber housing 110 of the atmospheric pressure plasma etching device 100 so as to generate plasma gas under an atmospheric pressure, and the etching chamber 112 is provided in the chamber housing 110 so as to receive the plasma gas from the plasma generator 120 to etch the substrate 10.

The plasma generator 120 includes a gas receiver 121 to receive process gas from an exterior, two electrodes 122 and 123 facing each other, and a power supplier 124 to supply power to the two electrodes 122 and 123.

The gas receiver 121 receives the process gas from an exterior to provide the process gas to the space between the two electrodes 122 and 123. The process gas includes etching gas and plasma generation gas used to generate plasma gas. For example, in the present exemplary embodiment, the plasma generation gas may include nitrogen gas (N₂), and the etching gas may include fluorine-based gas or chlorine-based gas. The fluorine-based gas includes, for example, one of sulfur hexafluoride (SF₆), carbon tetrafluoride (CF₄), tri-fluoromethane (CHF₃), and octafluorocyclobutane (C₄F₈), and the chlorine-based gas includes one of, for example, a chlorine gas (Cl₂), hydrogen chloride (HCl), and boron chloride (BCl₃).

The plasma generation gas and the etching gas have flow rates in the ratio of about 300:1 to about 10:1. For example, the nitrogen gas (N₂) may have a flow rate in the range of about 200 (standard liters per minute (slpm) to about 300 slpm, and the sulfur hexafluoride gas (SF₆) and the chlorine gas (Cl₂) may have a flow rate of about 10 slpm.

Inactive gas may be further provided in the gas receiver 121 so as to promote the dissociation and the ionization of the etching gas. As an example of the present invention, the inactive gas may be argon gas (Ar) or helium gas (He).

A high voltage is applied to the upper electrode 122 of the two electrodes 122 and 123, and a ground voltage is applied to the lower electrode 123. The upper electrode 122 is spaced apart from the lower electrode 123 by a predetermined distance, and provided with a gas inlet hole 122a used to supply the inactive gas, the etching gas, and the plasma generation gas from the gas receiver 121 to the space between the two electrodes 122 and 123. Plasma gas is generated from the plasma generation gas, the etching gas, and the inactive gas supplied to the space between the two electrodes 122 and 123.

The lower electrode 123 is provided with a gas outlet hole 123a used to supply the plasma gas to the etching chamber 112. Accordingly, the plasma gas generated between the electrodes 122 and 123 is provided to the etching chamber 112 through the gas outlet hole 123a. The plasma gas output through the gas outlet hole 123a is supplied to the substrate 10 reciprocating in the etching chamber 112 by a substrate conveying device 113. Accordingly, an amorphous silicon layer formed on the substrate 10 may be etched by the plasma gas.

To increase an etch rate of the amorphous silicon layer, the substrate 10 may be heated at a predetermined temperature. In the present exemplary embodiment, the substrate 10 is preferably heated at the temperature of about 50° C. or more.

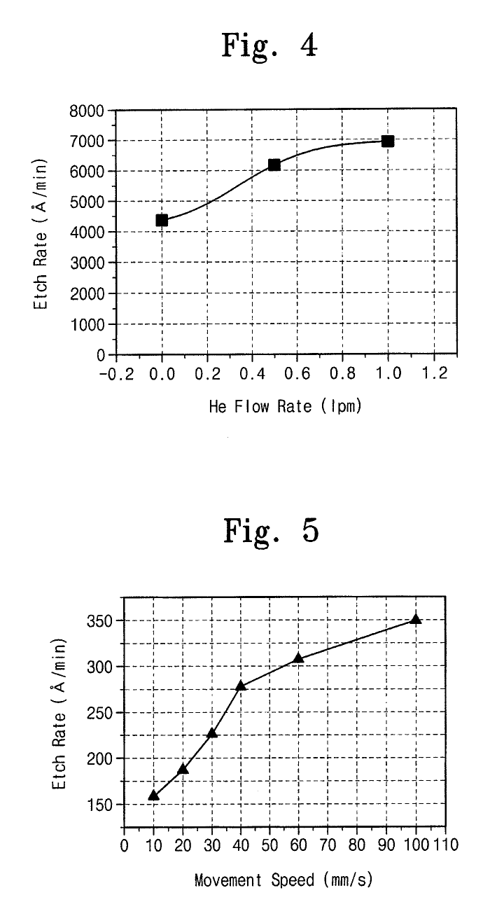

FIG. 4 is a graph showing an etch rate according to a flow rate of helium gas (He).

As shown in FIG. 4, the etch rate of the amorphous silicon layer is increased as the flow rate of helium gas (He) is increased with respect to the process gas supplied to the gas receiver (121 of FIG. 3). Accordingly, if the inactive gas is supplied to the gas receiver 121 in addition to the plasma generation gas and the etching gas, the etch rate of the amorphous silicon layer may be further increased.

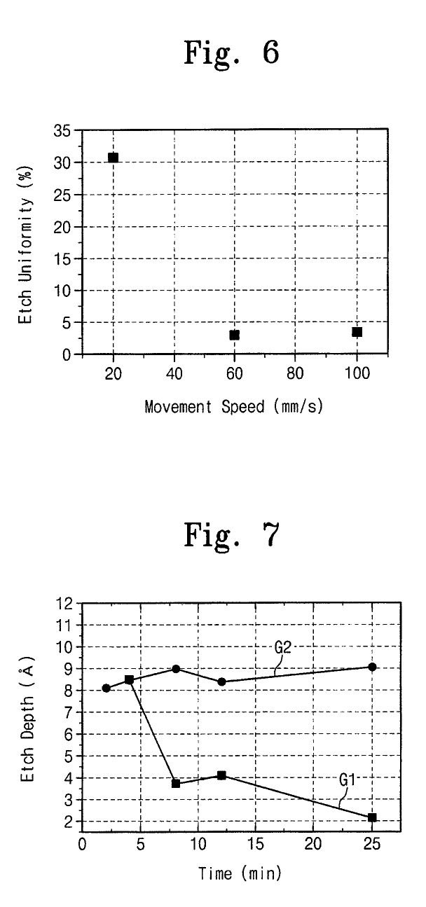

FIG. 5 is a graph showing the etch rate of the amorphous silicon layer according to the movement speed of the substrate 10, and FIG. 6 is a graph showing etch uniformity according to the movement speed of the substrate.

In FIG. 5, to measure the etch rate of the amorphous silicon layer, power of about 1.3 kW/1.5 kHz is applied to the upper electrode 122 of the plasma generator 120, and nitrogen gas (N₂) of about 200 sslpm, sulfur hexafluoride gas (SF₆) of about 10 slpm, and helium gas (He) of about 0.3 slpm are supplied to the gas receiver 121.

Referring to FIGS. 5 and 6, as the movement speed of the substrate 10 is increased, the etch rate and the etch uniformity of the amorphous silicon layer are increased. Therefore, the substrate 10 is preferably moved at a speed of about 50 mm/s or more.

FIG. 7 is a graph showing an etch rate according to a function of time, in which a first graph G1 of FIG. 7 shows an etch rate when the substrate 10 is heated at the temperature of about 25° C., and a second graph G2 of FIG. 7 shows an etch rate when the substrate 10 is heated at the temperature of about 70° C.

To measure the etch rate in FIG. 7, the upper electrode 122 of the plasma generator 120 is supplied with power of about 1.3 Kw/1.5 kHz, the gas receiver 121 is supplied with nitrogen gas (N₂) of about 200 slpm, sulfur hexafluoride gas (SF₆) of about 10 slpm, and helium gas (He) of about 1 slpm, and the substrate 10 is moved at a speed of about 100 mm/s.

Referring to FIG. 7, an etch rate of the amorphous silicon layer on the substrate 10 according to time is improved more when the substrate 10 is heated at the temperature of about 70° C. as compared with an etch rate when the substrate 10 is heated at the temperature of about 25° C. Therefore, the substrate 10 is preferably heated at the temperature of about 50° C. or more to improve the etch rate.

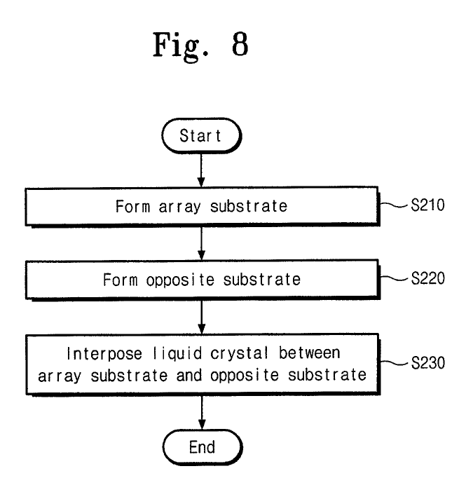

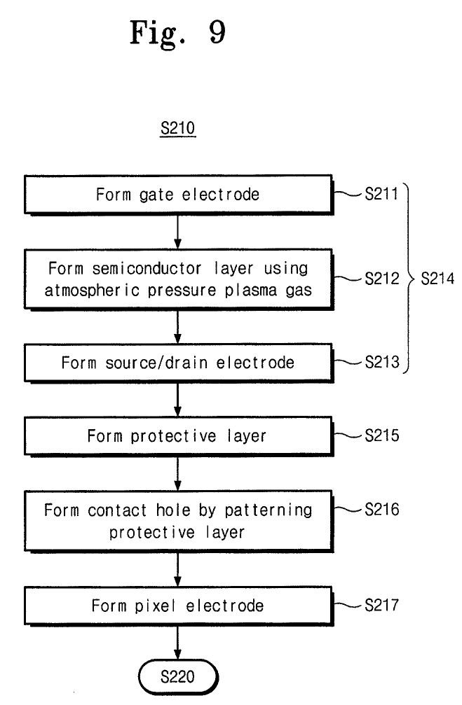

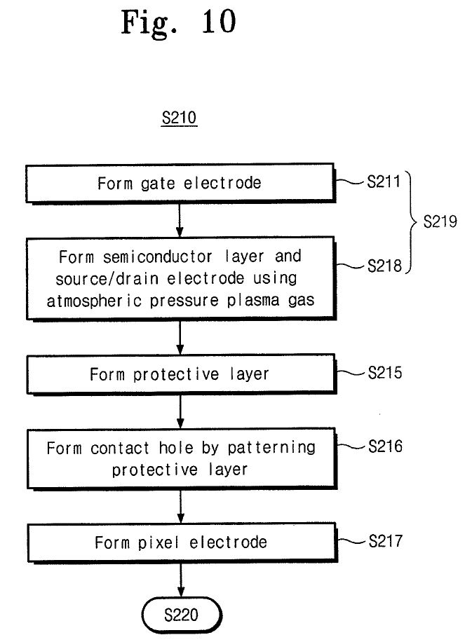

FIG. 8 is a flowchart showing a manufacturing process of a liquid crystal display according to an exemplary embodiment of the present invention. FIG. 9 is a flowchart showing the procedure of manufacturing an array substrate through a 5-mask process, and FIG. 10 is a flowchart showing the procedure of manufacturing an array substrate through a 4-mask process.

Referring to FIG. 8, after forming an array substrate (S210), an opposite substrate coupled to the array substrate while facing the array substrate is formed (S220). Then, a liquid crystal layer is interposed between the array substrate and the opposite substrate (S230), thereby forming the liquid crystal display.

When the array substrate is formed, the 5-mask process employing five masks or the 4-mask process employing four masks may be employed.

Hereinafter, the procedure of manufacturing the array substrate through the 5-mask process will be described.

As shown in FIG. 9, to form the array substrate, a thin film transistor is formed on a substrate (S214), and then a protective layer is formed to cover the thin film transistor (S215). Thereafter, the protective layer is patterned, thereby forming a contact hole to expose a drain electrode of the thin film transistor (S216). Finally, a pixel electrode is patterned (S217). In the 5-mask process, three masks are used to form the thin film transistor, and then two masks are additionally used to pattern the protective layer and the pixel electrode. Accordingly, the array substrate may be completed by using five masks.

Hereinafter, the process of forming the thin film transistor in the 5-mask process (S214) will be described. First, a gate layer is patterned to form a gate electrode (S211). Then, the amorphous silicon layer is patterned to form a semiconductor layer (S212). In this case, to etch the amorphous silicon layer, the atmospheric pressure plasma etching device shown in FIG. 1 is used. Accordingly, the amorphous silicon layer may be etched by atmospheric pressure plasma gas generated from the atmospheric pressure plasma etching device. Thereafter, a data layer is patterned to form a source and drain electrode (S213). Thus, the thin film transistor may be completed. In the present exemplary embodiment, the semiconductor layer may include, for example, an active layer including amorphous silicon and an ohmic contact layer including n+ amorphous silicon. In other words, the active layer and the ohmic contact layer are etched by using the atmospheric pressure plasma gas.

Meanwhile, according to one embodiment of the present invention, to pattern the protective layer to form the contact hole of exposing a drain electrode of the thin film transistor, the protective layer may be etched by using the atmospheric pressure plasma gas. In this case, the protective layer may include a silicon nitride layer or a silicon oxide layer.

Referring to FIG. 10, in the 4-mask process, two masks are used to form a thin film transistor, and then two masks are additionally used to pattern a protective layer and a pixel electrode.

Hereinafter, the process of forming the thin film transistor (S219) in the 4-mask process will be described. First, a gate layer is patterned to form a gate electrode (S211). Then, a data layer is patterned by using one mask, and an amorphous silicon layer is etched by using the data layer as a mask (S218). Accordingly, a semiconductor layer and a source/drain electrode may be formed through one mask process. To etch the amorphous silicon layer, the atmospheric pressure plasma etching device shown in FIG. 1 is used. Accordingly, the amorphous silicon layer may be etched by using atmospheric pressure plasma gas generated from the atmospheric pressure plasma etching device.

The process of etching the amorphous silicon layer of a liquid crystal display by using the atmospheric pressure plasma etching device has been described above. Hereinafter, an observation result for a thin film transistor having an amorphous silicon layer etched by using the atmospheric pressure plasma etching device will be described in detail.

Measurement results, which are described later, satisfy the following conditions for an atmospheric pressure plasma etching process. In detail, according to the conditions for the atmospheric pressure plasma etching process, a power of about 1.3 kW/15 kHz is applied to the upper electrode 122 of the plasma generator 120, and nitrogen gas (N₂) of about 200 slpm, sulfur hexafluoride gas (SF₆) of about 8.5 slpm, and helium gas (He) of about 1 slpm are provided to the gas receiver 121. The substrate 10 is heated at the temperature of about 70° C. The substrate 10 is transferred at a speed of about 100 mm/s.

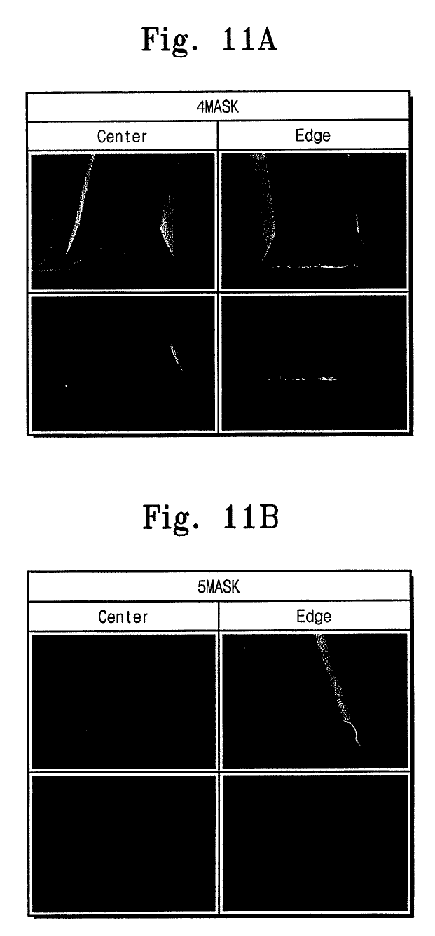

FIG. 11A is a view showing a profile of an active layer including amorphous silicon after etching the active layer by using the atmospheric pressure plasma etching device through the 4-mask process, and FIG. 11B is a view showing a profile of an active layer including amorphous silicon after etching the active layer by using an atmospheric pressure plasma etching device through the 5-mask process. FIGS. 11A and 11B are views showing measurement results obtained using a scanning electron microscope (SEM).

As shown in FIGS. 11A and 11B, according to the measurement result of the profile, although the active layer of the liquid crystal display is etched by using the atmospheric pressure plasma etching device, the same results are obtained as compared with the case in which the active layer is etched by using a conventional vacuum plasma etching device.

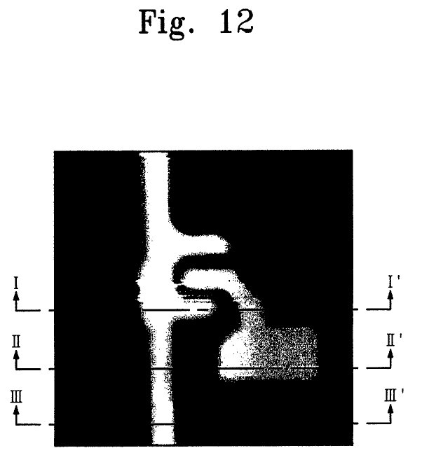

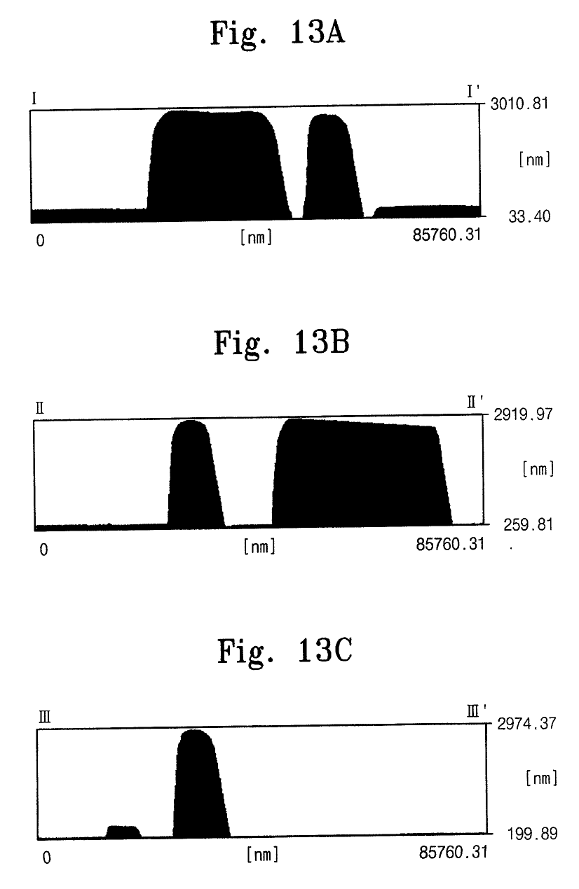

FIG. 12 is a plan view showing the thin film transistor in the 4-mask process for the liquid crystal display, and FIGS. 13A to 13C are sectional views taken along lines I-I′, II-II′, and III-III′ of FIG. 12. Especially, FIG. 12 is a view showing a measurement result obtained by using an atomic force microscope (AFM).

As shown in FIGS. 12 to 13C, as an observation result of the surface of the thin film transistor of the liquid crystal display, which is manufactured through the 4-mask process, the thickness of a layer is uniformly maintained according to the position of the layer, so that a problem related to surface roughness does not occur.

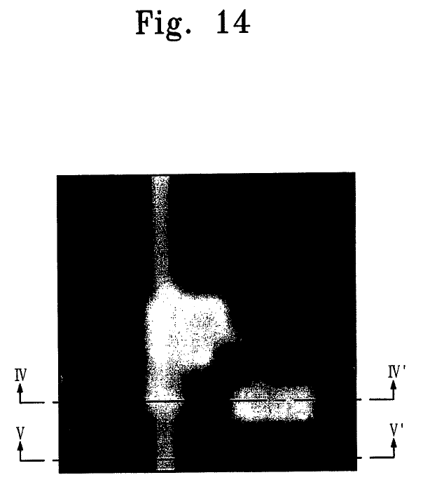

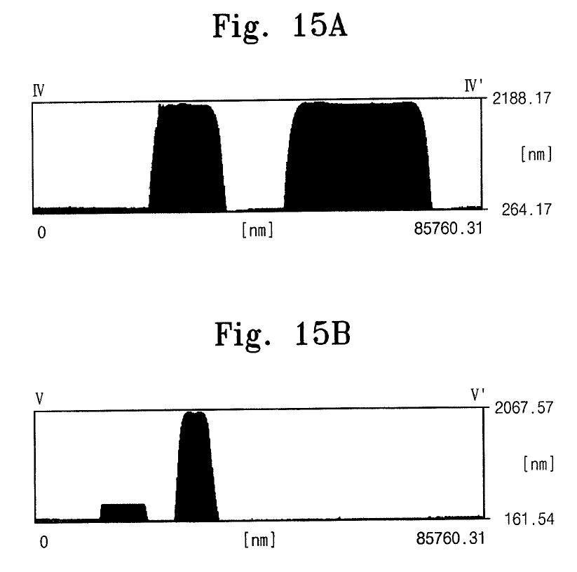

FIG. 14 is a plan view showing the thin film transistor in the 5-mask process for the liquid crystal display. FIGS. 15A and 15B are sectional views taken along lines IV-IV′ and V-V′ of FIG. 14. Especially, FIG. 14 is a view showing a measurement result obtained through an atomic force microscope (AFM).

As shown in FIGS. 14 to 15B, as an observation result of the surface of the thin film transistor of the liquid crystal display, which is manufactured through the 5-mask process, the thickness of a layer is uniformly maintained according to the position of the layer, so that problem related to surface roughness does not occur.

Table 1 shows a measurement result of an off-current Ioff, an on-current Ion, a threshold voltage Vth, and parasitic capacitance Cgs between a gate/source according to numbers of glasses manufactured through the 4-mask process. In table 1, glass numbers 1 to 7 represent glasses etched by using the atmospheric pressure plasma etching device, and glass numbers 9 and 10 represent glasses etched by using a conventional vacuum plasma etching device.

TABLE 1

| | Atmospheric pressure plasma etching | | | | | | Related art | |
|---|---|---|---|---|---|---|---|---|
| Symbol | 1 | 2 | 3 | 4 | 5 | 7 | 9 | 10 |
| Ioff | 3.74E−12 | 3.52E−12 | 3.29E−12 | 3.08E−12 | 4.95E−12 | 4.93E−12 | 4.65E−12 | 3.75E−12 |
| Ion | 5.24E−06 | 5.71E−06 | 5.86E−06 | 6.03E−06 | 6.59E−06 | 6.26E−06 | 6.42E−06 | 6.49E−06 |
| Vth | 3.12E+00 | 2.94E+00 | 2.93E+00 | 2.91E+00 | 2.51E+00 | 2.56E+00 | 2.37E+00 | 2.43E+00 |
| Cgs | 4.98E−11 | 4.91E−11 | 5.02E−11 | 4.94E−11 | 5.04E−11 | 5.09E−11 | 5.00E−11 | 5.01E−11 |

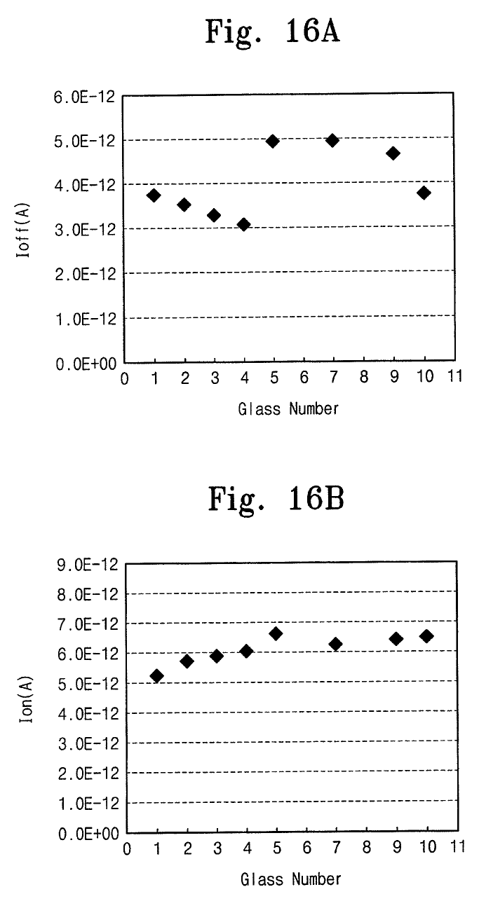

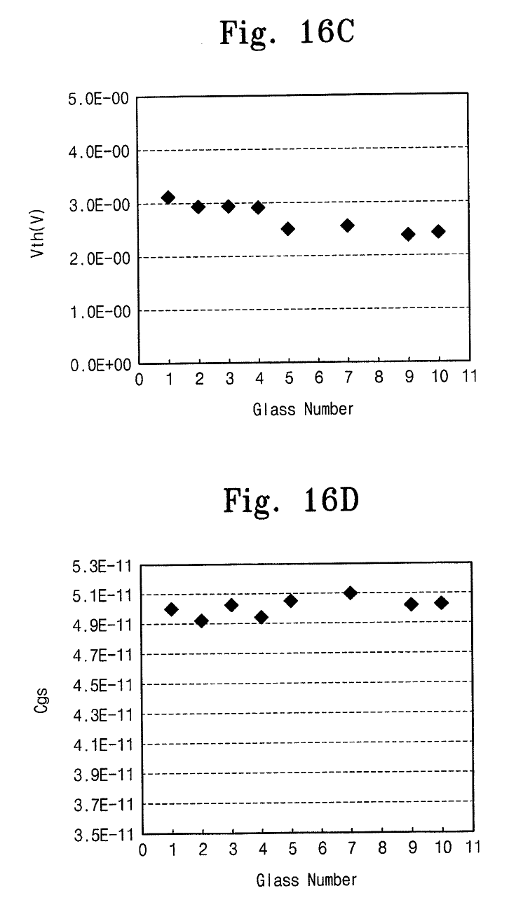

FIGS. 16A to 16D are graphs showing the data of table 1. In detail, FIG. 16A is a graph representing the off-current Ioff measured according to the glass numbers, and FIG. 16B is a graph showing the on-current Ion measured according to the glass numbers. FIG. 16C is a graph showing the threshold voltage Vth measured according to the glass numbers, and FIG. 16D is a graph showing the parasitic capacitance Cgs between the gate and the source measured according to the glass numbers.

Referring to FIGS. 16A to 16D, when the etching process is performed by using the plasma gas, the off-current Ioff, the on-current Ion, the threshold voltage Vth, and the parasitic capacitance Cgs are substantially identical to those obtained through a conventional etching process using vacuum plasma gas.

Table 2 shows a measurement result of an off-current Ioff, an on-current Ion, a threshold voltage Vth, parasitic capacitance Cgs between a gate and a source, and parasitic capacitance Cds between a drain and a source according to numbers of glasses manufactured through the 5-mask process. In table 2, glass numbers 2 to 7 represent glasses etched by using the atmospheric pressure plasma etching device, and glass numbers 9 and 10 represent glasses etched by using the conventional vacuum plasma etching device.

TABLE 2

| | Atmospheric pressure plasma etching | | | | | | Related art | |
|---|---|---|---|---|---|---|---|---|
| Symbol | 2 | 3 | 4 | 5 | 6 | 7 | 9 | 10 |
| Ioff | 4.82E−12 | 2.48E−12 | 2.20E−12 | 3.15E−12 | 4.37E−12 | 5.26E−12 | 3.12E−12 | 2.91E−12 |
| Ion | 3.66E−06 | 3.90E−06 | 3.96E−06 | 3.91E−06 | 3.30E−06 | 3.81E−06 | 3.81E−06 | 3.81E−06 |
| Vth | 1.91E+00 | 2.23E+00 | 2.26E+00 | 2.36E+00 | 2.34E+00 | 2.29E+00 | 2.41E+00 | 2.49E+00 |
| Cgs | 5.07E−11 | 5.22E−11 | 5.02E−11 | 5.33E−11 | 5.36E−11 | 5.17E−11 | 5.12E−11 | 5.15E−11 |
| Cds | 1.43E−10 | 1.44E−10 | 1.45E−10 | 1.46E−10 | 1.44E−10 | 1.44E−10 | 1.44E−10 | 1.45E−10 |

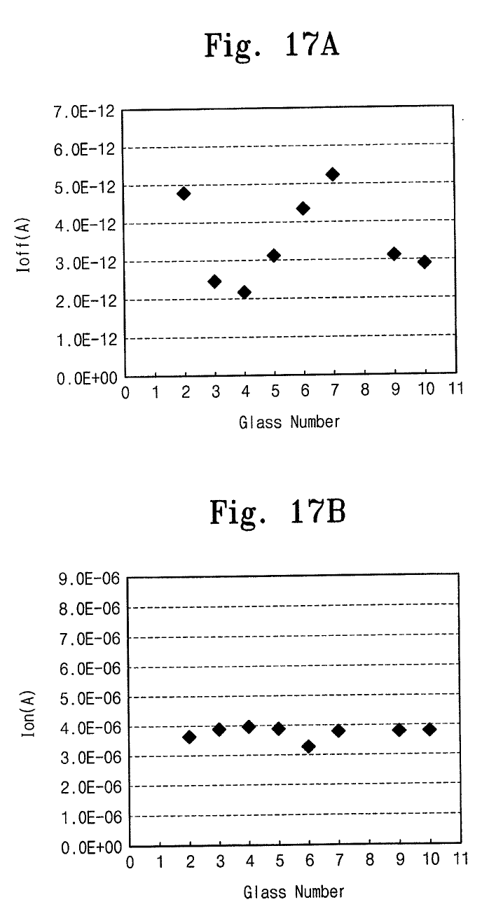

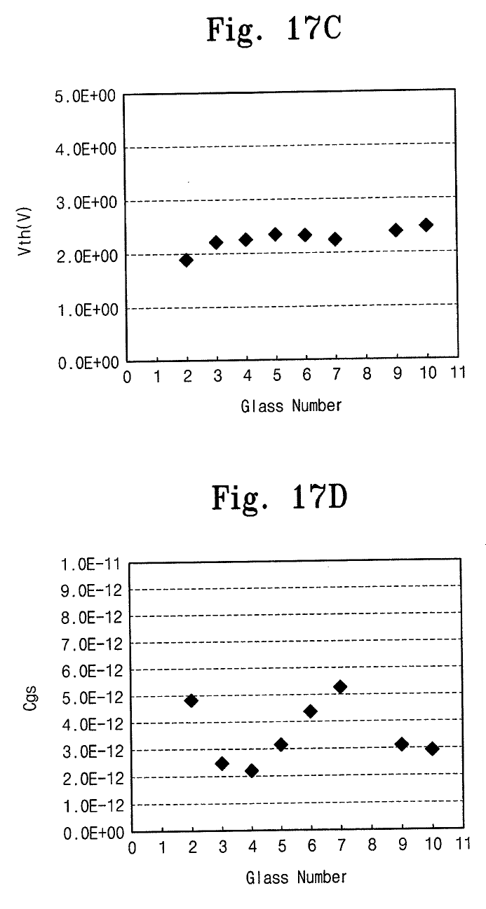

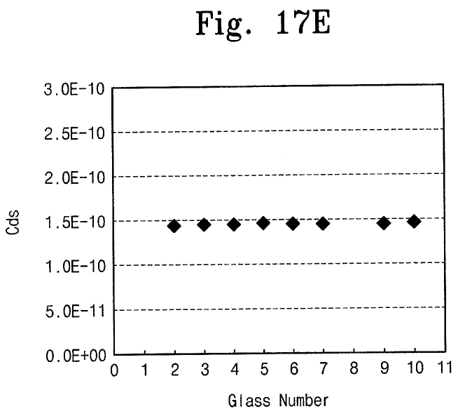

FIGS. 17A to 17E are graphs showing the data of table 2. In detail, FIG. 17A is a graph representing the off-current Ioff measured according to the glass numbers, and FIG. 17B is a graph showing the on-current Ion measured according to the glass numbers. FIG. 17C is a graph showing the threshold voltage Vth measured according to the glass numbers, and FIG. 17D is a graph showing the parasitic capacitance Cgs between the gate and the source according to the glass numbers. FIG. 17E is a graph showing the parasitic capacitance Cds between the drain and the source measured according to the glass numbers.

Referring to FIGS. 17A to 17E, when the etching process is performed by using the plasma gas, the off-current Ioff, the on-current Ion, the threshold voltage Vth, and the parasitic capacitance Cgs and Cds are substantially identical to those obtained through a conventional etching process using a vacuum plasma gas.

As described above, a layer used for the liquid crystal display is etched by using the atmospheric pressure plasma etching device, so that vacuum equipment is not required, and the price of etching equipment is lowered. In addition, the layer is etched through a scan scheme, so that the difficulty in the manufacturing process resulting from the increase of the size of the substrate may be overcome.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A method of etching an amorphous silicon layer, the method comprising:
providing a substrate with an amorphous silicon layer formed thereon into an atmospheric pressure plasma etching device;
providing a plasma generation gas and a etching gas to a plasma generator of the atmospheric pressure plasma etching device;
generating an atmospheric pressure plasma gas between two electrodes provided in the plasma generator, in which the two electrodes face each other; and
repeatedly passing the substrate through the plasma generator at a predetermined speed, thereby etching the amorphous silicon layer on the substrate by using the atmospheric pressure plasma gas generated from the plasma generator.

2. The method of claim 1, wherein the plasma generation gas and the etching gas have flow rates in a ratio of about 300:1 to about 10:1.

3. The method of claim 2, wherein the etching gas comprises one of a fluorine-based gas or a chlorine-based gas.

4. The method of claim 3, wherein the fluorine-based gas comprises one of sulfur hexafluoride (SF₆), carbon tetrafluoride (CF₄), tri-fluoromethane (CHF₃), and octafluorocyclobutane (C₄F₈), and wherein the chlorine-based gas comprises one of chlorine gas (Cl₂), hydrogen chloride (HCl), and boron chloride (BCl₃).

5. The method of claim 2, wherein the plasma generation gas comprises a nitrogen gas (N₂).

6. The method of claim 1, wherein an inactive gas is further provided to the plasma generator together with the plasma generation gas and the etching gas to promote dissociation and ionization of the etching gas.

7. The method of claim 6, wherein the inactive gas comprises one of argon (Ar) and helium (He).

8. The method of claim 1, wherein the substrate passes through the plasma generator at a speed of about 50 mm/s.

9. The method of claim 1, wherein the substrate is heated at a temperature of about 50° C.

10. A method of manufacturing a liquid crystal display, the method comprising:
forming an array substrate provided with a thin film transistor;
forming an opposite substrate coupled to the array substrate while facing the array substrate; and
interposing a liquid crystal layer between the array substrate and the opposite substrate,
wherein forming the thin film transistor on the array substrate comprises:
forming a gate electrode;
forming a semiconductor layer on the gate electrode by etching an amorphous silicon layer using an atmospheric pressure plasma gas; and
forming a source and drain electrode overlapping with the semiconductor layer.

11. The method of claim 10, wherein etching the amorphous silicon layer using the atmospheric pressure plasma gas comprises:
providing a substrate with the amorphous silicon layer formed thereon into an atmospheric pressure plasma etching device;
providing a plasma generation gas and an etching gas to a plasma generator of the atmospheric pressure plasma etching device;
generating an atmospheric pressure plasma gas between two electrodes provided in the plasma generator, in which the two electrodes face each other; and
repeatedly passing the substrate through the plasma generator at a predetermined speed, thereby etching the amorphous silicon layer on the substrate by using the atmospheric pressure plasma gas generated from the plasma generator.

12. The method of claim 11, wherein the plasma generation gas and the etching gas have flow rates in a ratio of about 300:1 to about 10:1.

13. The method of claim 12, wherein the etching gas comprises one of a fluorine-based gas and a chlorine-based gas, and the plasma generation gas comprises nitrogen gas (N₂).

14. The method of claim 13, wherein the fluorine-based gas comprises one of sulfur hexafluoride (SF₆), carbon tetrafluoride (CF₄), tri-fluoromethane (CHF₃), and octafluorocyclobutane (C₄F₈), and wherein the chlorine-based gas comprises one of chlorine gas (Cl₂), hydrogen chloride (HCl), and boron chloride (BCl₃).

15. The method of claim 11, wherein an inactive gas is further provided to the plasma generator together with the plasma generation gas and the etching gas to promote dissociation and ionization of the etching gas, in which the inactive gas comprises one of argon (Ar) and helium (He).

16. The method of claim 11, wherein the substrate passes through the plasma generator at a speed of about 50 mm/s.

17. The method of claim 11, wherein the substrate is heated at a temperature of about 50° C.

18. The method of claim 10, wherein the semiconductor layer comprises an active layer and an ohmic contact layer, wherein the active layer comprises an amorphous silicon layer, and the ohmic contact layer comprises an n+ amorphous silicon layer.

19. The method of claim 10, wherein the forming of the array substrate further comprises:
forming a protective layer that covers the thin film transistor;
forming a contact hole, which exposes a drain electrode of the thin film transistor, in the protective layer; and
forming a pixel electrode provided on the protective layer, in which the pixel electrode is electrically connected to the drain electrode through the contact hole.
